(19) United States
(12) Patent Application Publication
(10) Pub. No.: US 2023/0187522 A1
(43) Pub. Date: Jun. 15, 2023

(54) SEMICONDUCTOR STRUCTURE AND METHOD FOR MANUFACTURING SEMICONDUCTOR STRUCTURE

(71) Applicant: CHANGXIN MEMORY TECHNOLOGIES, INC., Hefei City (CN)

(72) Inventors: Shuhao ZHANG, Hefei (CN); Ning Li, Hefei (CN)

(21) Appl. No.: 18/166,022

(22) Filed: Feb. 8, 2023

Related U.S. Application Data
(63) Continuation of application No. PCT/CN2022/091989, filed on May 10, 2022.

(30) Foreign Application Priority Data
Jul. 9, 2021 (CN) 202110779623.3

(51) Int. Cl. H01L 29/45; H01L 29/40

(52) U.S. Cl. CPC H01L 29/456; H01L 29/401

(57) ABSTRACT

A semiconductor structure and a method for manufacturing a semiconductor structure are provided. The semiconductor structure includes a base, a contact hole, a barrier layer, and a conductive contact structure. The base includes an active area. A drain area and a source area are formed in the active area. The contact hole extends from a surface of the base to at least one of the source area or the drain area. The barrier layer is arranged on a bottom surface of the conductive contact structure. The contact hole is filled with the conductive contact structure. The conductive contact structure includes a contact layer, and the contact layer is in contact with the source area and/or the drain area.

### CROSS-REFERENCE TO RELATED APPLICATIONS

This is a continuation application of International Patent Application No. PCT/CN2022/091989, filed on May 10, 2022, which claims priority to Chinese Patent Application No. 202110779623.3, filed on Jul. 9, 2021 and entitled “SEMICONDUCTOR STRUCTURE AND METHOD FOR MANUFACTURING SEMICONDUCTOR STRUCTURE”. The disclosures of International Patent Application No. PCT/CN2022/091989 and Chinese Patent Application No. 202110779623.3 are incorporated by reference herein in their entireties.

### BACKGROUND

As a common device in a semiconductor manufacturing process, a Metal Oxide Semiconductor Field Effect Transistor (MOSFET) is usually heavily doped in an active area to form a source area and a drain area, and forms a conductive contact structure extending into the source area and the drain area, so as to connect the current (conduction current) between the source area and drain area to the outside.

However, in practical products, there are often the problems of lower conduction current and higher leakage current due to the conductive contact structure.

### SUMMARY

The disclosure relates to the technical field of integrated circuits, and in particular to a semiconductor structure and a method for manufacturing a semiconductor structure.

According to various embodiments of the disclosure, a semiconductor structure and a method for manufacturing a semiconductor structure are provided.

According to various embodiments of the disclosure, a semiconductor structure is provided, which includes a base, a contact hole, a barrier layer, and a conductive contact structure.

The base includes an active area, and a drain area and a source area are formed in the active area.

The contact hole extends from a surface of the base to at least one of the source area or the drain area.

The barrier layer is arranged on a bottom surface of the conductive contact structure.

The contact hole is filled with the conductive contact structure, and the conductive contact structure includes a contact layer. The contact layer is in contact with the at least one of the source area or the drain area.

According to various embodiments of the disclosure, a method for manufacturing a semiconductor structure is further provided, which includes the following operations.

A base is provided, in which the base includes an active area, and a drain area and a source area are formed in the active area.

A contact hole is formed in the base, in which the contact hole extends from a surface of the base to at least one of the source area or the drain area.

A barrier layer is formed.

A conductive contact structure is formed.

The barrier layer is arranged on a bottom surface of the conductive contact structure. The contact hole is filled with the conductive contact structure, and the conductive contact structure includes a contact layer. The contact layer is in contact with the at least one of the source area or the drain area.

Details of one or more embodiments of the disclosure are set forth in the following accompanying drawings and description. Other features, purposes, and advantages of the disclosure will become apparent from the description, accompanying drawings, and claims.

### BRIEF DESCRIPTION OF THE DRAWINGS

In order to describe the technical solutions in the embodiments of the disclosure or the technical solutions in the conventional technology more clearly, the accompanying drawings required to be used in the embodiments or the conventional technology will be simply introduced below. It is apparent that the accompanying drawings in the following description show merely some embodiments of the disclosure, and persons of ordinary skill in the art may still derive other drawings from these accompanying drawings without any creative effort.

FIG. 1 is a flowchart of a method for manufacturing a semiconductor structure according to an embodiment;

FIG. 2 to FIG. 7 are schematic diagrams of a structure in a process of manufacturing a semiconductor structure according to an embodiment;

FIG. 8 is a schematic diagram of a semiconductor structure according to an embodiment; and

FIG. 9 is a schematic diagram of a semiconductor structure according to another embodiment.

Description of reference numerals: 100—base, 110—substrate, 111—active area, 1111—source area, 1112—drain area, 120—dielectric layer, 100a—contact hole, 200—barrier layer, 201—barrier material layer, 300—conductive contact layer, 310—contact layer, 311—contact raw material layer, and 320—conductive metal structure.

In order to better describe and illustrate the embodiments and/or examples of whose invention disclosed herein, reference may be made to one or more of the drawings. The additional details or examples used to describe the drawings are not to be construed as limiting the scope of any of the disclosed inventions, the presently described embodiments and/or examples, and the best model for these inventions which is currently understood.

### DETAILED DESCRIPTION

In order to facilitate the understanding of the disclosure, the disclosure will be described more fully below hereinafter with reference to the accompanying drawings. Embodiments of the disclosure are shown in the accompanying drawings. However, the disclosure may be implemented in many different forms and is not limited to the embodiments described herein. On the contrary, these embodiments are provided for the purpose of making the disclosed contents of the disclosure more comprehensive.

Unless defined otherwise, all technical and scientific terms used herein have the same meanings as commonly understood by those skilled in the art to which the disclosure belongs. The terminology used in the specification of the disclosure is for a purpose of describing specific embodiments only, and is not intended to limit the disclosure.

It should be understood that when elements or layers are referred to as “on”, “adjacent to”, “connected to”, or “coupled to” other elements or layers, it may be directly on, adjacent to, connected to, or coupled to other elements or layers, or there may be intermediate elements or layers. On the contrary, when the element is “directly on”, “directly adjacent to”, “directly connected to” or “directly coupled to” other elements or layers, there is no intermediate element or layer. It should be understood that, although the terms first, second and third may be used to describe elements, components, areas, layers, doping types, and/or parts, those elements, components, areas, layers, doping types, and/or parts should not be limited by those terms. These terms are used only to distinguish one element, component, area, layer, doping type, or part from another element, component, area, layer, doping type, or part. Therefore, the first element, component, area, layer, doping type, or part discussed below may be represented as a second element, component, area, layer, or part without departing from the teaching of the disclosure.

Spatially relational terms such as “below”, “under”, “lower”, “beneath”, “on”, and “upper” may be used herein for describing the relationship between an element or feature shown in the drawings and other elements or features. It should be understood that, other than the orientation shown in the drawings, the spatially relational terms include different orientations of the devices in use and operation. For example, if the device in the drawings is reversed, elements or features described as “under”, or “below”, or “beneath” other elements will be oriented to be “above” other elements or features. Therefore, the exemplary terms “under” and “below” may include both upper and lower orientations. In addition, the device may be otherwise oriented (for example, rotated by 90° or other orientations) and the spatial descriptors used herein are interpreted accordingly.

As used herein, the singular forms “a/an”, “one”, and “the/said” may also include the plural forms, unless the context clearly indicates otherwise. It should be understood that the terms “comprising/including”, or “having” specify the existence of the stated features, integers, steps, operations, components, parts, or combinations thereof, but do not exclude the possibility of the existence or addition of one or more of the other features, integers, steps, operations, components, parts or combinations thereof. Meanwhile, in the specification, the term “and/or” includes any and all combinations of the related listed items.

The embodiments of the disclosure are described herein with reference to cross-sectional illustrations of schematic diagrams of the preferred embodiments (and intermediate structures) of the disclosure. Thus, variations from the shapes shown may be expected as a result, for example, of manufacturing techniques and/or tolerances. Therefore, the embodiments of the disclosure shall not limited to the specific shape of the area shown herein, but shall include the variations in the shape, for example, a shape variation due to manufacturing techniques.

As described in the BACKGROUND, in practical products, there are often the problems of lower conduction current and higher leakage current. The inventor found that the reasons for the problems are as follows.

A procedure for manufacturing a conductive contact structure is usually as follows. Firstly, a contact hole extending to a source area and a drain area is formed. Then, a layer of cobalt (Co) is deposited in the contact hole. Subsequently, heat treatment is performed to make the Co diffuse into the source area and the drain area (the material of the source area and the drain area is usually heavily doped silicon) to react with the source area and the drain area, so as to form a cobalt silicide (CoSi) contact layer, so that the conductive contact structure can form a good ohmic contact with the source area and drain area arranged around the conductive contact structure through the CoSi, thereby effectively reducing the contact resistance between the conductive contact structure and the source area and between the conductive contact structure and the drain area.

However, the current process often results in the concentration of the CoSi below the conductive contact structure. Further, the device is transversely conducted through a channel. Therefore, the concentration of the CoSi below the conductive contact structure may increase the transverse conduction resistance. Particularly, if the conductive contact structure is too deep, the CoSi will be arranged away from the conductive channel, which will increase the transverse conduction resistance, thereby reducing the conduction current.

Moreover, if the conductive contact structure is too deep, it may extend beyond a source doping area and a drain doping area to connect to the substrate, thereby increasing the leakage current.

Based on the above reasons, the disclosure provides an improved conductive contact structure, a semiconductor structure with improved device performance, and a method for manufacturing a semiconductor structure.

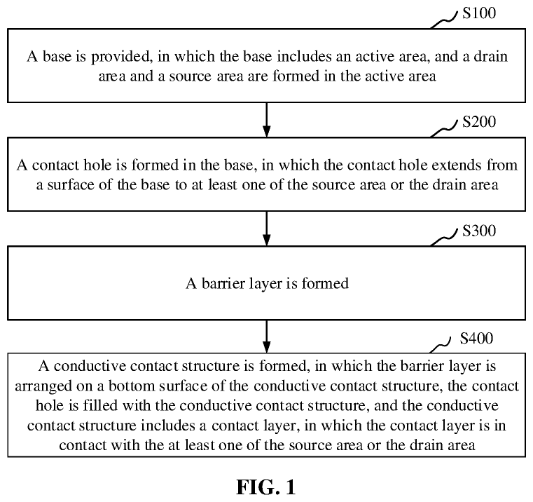

In one embodiment, with reference to FIG. 1, a method for manufacturing a semiconductor structure is provided, which includes the following operations.

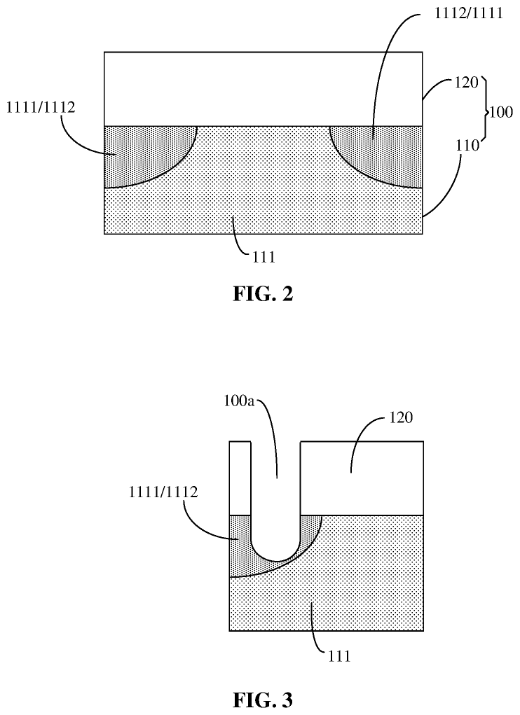

In S100, a base 100 is provided, in which the base 100 includes an active area 111, and a drain area 1112 and a source area 1111 are formed in the active area 111, with reference to FIG. 2.

In S200, a contact hole 100a is formed in the base 100, in which the contact hole 100a extends from a surface of the base 100 to at least one of the source area 1111 or the drain area 1112, with reference to FIG. 3.

In S300, a barrier layer 200 is formed, with reference to FIG. 5.

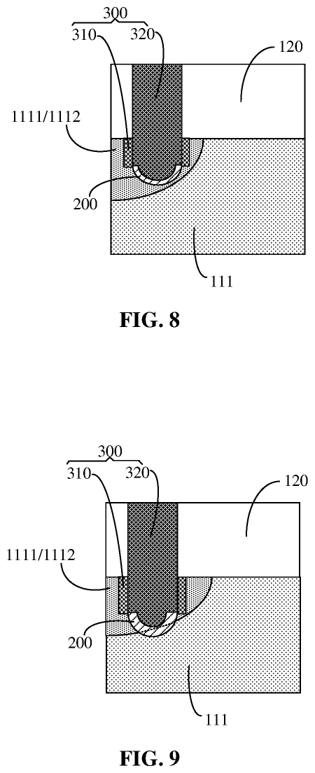

In S400, a conductive contact structure 300 is formed, with reference to FIG. 8.

The barrier layer 200 is arranged on a bottom surface of the conductive contact structure 300. The contact hole 100a is filled with the conductive contact structure 300, and the conductive contact structure includes a contact layer 310. The contact layer 310 is in contact with the at least one of the source area 1111 or the drain area 1112.

In S100, the active area 111 may be a P-type active area, or may also be an N-type active area. The P-type active area may form an N-Metal-Oxide-Semiconductor (NMOS) device, and the N-type active area may form a P-Metal-Oxide-Semiconductor (PMOS) device.

As an example, the base 100 may include a substrate 110. The substrate 110 may include, but is not limited to, a silicon substrate. A P-type well area or an N-type well area may be formed in the substrate 110, and a shallow trench isolation structure may be formed in the substrate. The P-type well area or the N-type well area is isolated into a plurality of P-type active areas or N-type active areas spaced apart from each other by the shallow trench isolation structure.

Both sides of the active area 111 may be heavily doped through an ion implantation process and the like, so as to form the drain area 1112 and the source area 1111. Both sides of the P-type active area may be subjected to N-type heavy doping, so as to form the drain area 1112 and the source area 1111. Both sides of the N-type active area may be subjected to P-type heavy doping, so as to form the drain area 1112 and the source area 1111.

In S200, firstly, a patterned mask layer may be formed on a surface of the base 100. The patterned mask layer is provided with a mask opening exposing the surface of the base, and the mask opening defines the shape and the position of the contact hole 100a. Then, the base 100 is etched on the basis of the patterned mask layer, so as to form the contact hole 100a.

In S300, the barrier layer 200 is an insulating dielectric layer that can block the transmission of current. A material of the barrier layer 200 may be silicon dioxide, silicon nitride, silicon oxynitride, etc.

In S400, a material of the contact layer 310 may include, but is not limited to, a metal silicide (such as CoSi), etc. The contact layer can form a good ohmic contact with the source area 1111 and the drain area 1112.

In this embodiment, the barrier layer 200 is formed before the conductive contact structure 300 is formed. The barrier layer 200 is arranged on a bottom surface of the conductive contact structure 300, so as to effectively prevent the contact layer 310 from concentrating below the conductive contact structure. In this case, the contact layer 310 can provide a good current transmission by forming a good ohmic contact between the side surface of the contact layer and at least one of the source area 1111 or the drain area 1112, so as to effectively reduce the transverse resistance, thereby effectively increasing the current of the source and the drain.

Here, it is worth noting that, in S200 in this embodiment, in order to reduce the process complexity, the contact hole 100a may be formed simultaneously with other through holes at other positions on the same wafer. In this case, in addition to the shape and position of the contact hole 100a, the opening in the patterned mask layer may also simultaneously define the shapes and positions of other through holes with other functions. Then, the contact hole 100a and other through holes may be formed simultaneously on the basis of the patterned mask layer.

However, in this case, affected by other through holes at other positions, the contact hole 100a may need to extend by a greater depth in at least one of the source area 1111 or the drain area 1112, and may even extend through at least one of the source area 1111 or the drain area 1112 to the active area below at least one of the source area 1111 or the drain area 1112, resulting in a leakage risk between the conductive contact structure 300 and the substrate.

In this embodiment, the barrier layer 200 is formed before the conductive contact structure 300 is formed. The barrier layer 200 is arranged on the bottom surface of the conductive contact structure 300, so as to effectively reduce the leakage risk between the conductive contact structure 300 and the substrate.

Of course, in this embodiment, the contact hole 100a may also be formed independently, which is not limited thereto in the disclosure.

In one embodiment, with reference to FIG. 2 and FIG. 3, the base 100 includes a substrate 110 in which an active area 111 is formed. Meanwhile, the base 100 further includes a dielectric layer 120 arranged on the substrate 110. The contact hole 100a extends from a surface of the dielectric layer 120 to at least one of the source area 1111 or the drain area 1112.

That is, in this embodiment, the contact hole 100a is formed after the dielectric layer 120 is formed on the substrate 110, so as to facilitate the unified processing and manufacturing of a plurality of devices.

Of course, the disclosure is not limited thereto. For example, in some embodiments, the base 100 may only include the substrate 110.

In one embodiment, the barrier layer 200 is arranged inside the contact hole 100a.

In this case, the barrier layer 200 may be conveniently formed on the bottom surface of the conductive contact structure 300.

Further, in this case, S300 may include the following operations.

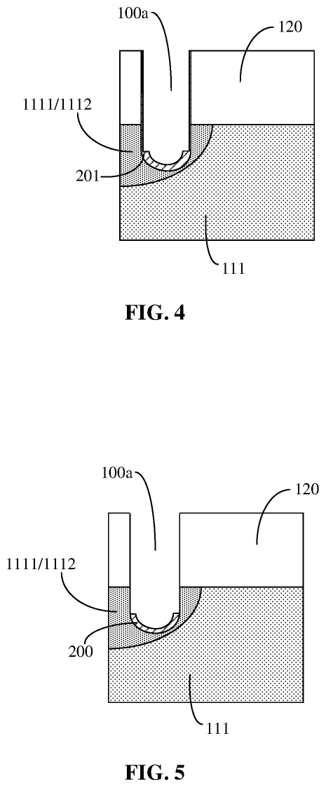

In S310, a barrier material layer 201 is formed on an inner wall of the contact hole 100a on the basis of a first mask, in which the first mask is provided with a first opening, and the first opening exposes the contact hole 100a, with reference to FIG. 4.

In S320, a portion, which is arranged on a sidewall of the contact hole 100a, of the barrier material layer 201 is at least removed, in which a remaining portion of the barrier material layer 201 forms the barrier layer 200, with reference to FIG. 5.

In S310, as an example, the first mask may be a mask with a first opening. The first mask can cover the surface of the base 100 before S310 is performed. This mask only exposes the contact hole 100a, so that the barrier material layer 201 is formed on the inner wall of the contact hole 100a.

Of course, the disclosure is not limited thereto. For example, in some other examples, the first mask may also be the patterned mask layer for forming the contact hole 100a as described above. That is, after the contact hole 100a is formed through the patterned mask layer in S200, a barrier material layer 201a is formed on the inner wall of the contact hole 100a by continuing using the patterned mask layer as a first mask.

In S320, after the portion, which is arranged on the sidewall of the contact hole 100a, of the barrier material layer 201 is removed, the formed barrier layer 200 is arranged inside the contact hole 100a, and is arranged at the bottom portion of the contact hole 100a.

Further, with reference to FIG. 9, when the contact hole 100a is arranged inside the contact hole 100a, and extends from the surface of the base to the active area 111 arranged below at least one of the source area 1111 or the drain area 1112, the barrier layer 200 may be provided to cover a portion, which extends beyond at least one of the source area 1111 or the drain area 1112 and into the active area 111, of the contact hole 100a, which can effectively prevent the conductive contact structure 300 from being in contact with the active area 111 outside at least one of the source area 1111 or the drain area 1112, thereby better preventing the leakage between the conductive contact structure 300 and the bottom portion of the substrate.

Of course, in other embodiments, the barrier layer 200 may also be formed in other manners. For example, after the contact hole 100a is formed, a thermal oxidation process is performed, so as to oxidize the wall of the contact hole 100a to form an oxide layer. After that, the oxide layer arranged on the side surface of the contact hole is removed, so that the oxide layer remained at the bottom portion of the contact hole forms the barrier layer 200. In this case, the barrier layer 200 is arranged outside the contact hole 100a and is connected to the contact hole 100a.

In one embodiment, S310 includes the following operation. The barrier material layer 201 is deposited on the inner wall of the contact hole 100a on the basis of the first mask through an atomic layer deposition process, with reference to FIG. 4.

The barrier material layer 201 with good quality may be formed through the atomic layer deposition process.

Meanwhile, an anisotropic barrier material layer 210 may be grown in the contact hole 100a through the atomic layer deposition process. The inner wall of the contact hole 100a includes a bottom wall and a sidewall. In this case, the thickness of the barrier material layer 201 formed on the bottom wall of the contact hole 100a is greater than the thickness of the barrier material layer 201 formed on the sidewall of the contact hole 100a.

The ratio of the thickness of the barrier material layer 201 formed on the bottom wall of the contact hole 100a to the thickness of the barrier material layer 201 formed on the sidewall of the contact hole 100a may be controlled in the range from 4:1 to 6:1. For example, the ratio of the thickness of the barrier material layer 201 formed on the bottom wall of the contact hole 100a to the thickness of the barrier material layer 201 formed on the sidewall of the contact hole 100a may be controlled as about 5:1.

Based on this, further, in this case, S320 may include the following operation.

The barrier material layer 201 is etched through an isotropic etching process, with reference to FIG. 5.

When the barrier material layer 201 is etched through the isotropic etching process, the etching rate of the barrier material layer 201 in all directions is the same. Therefore, in this case, the whole barrier material layer 201 may be etched. Meanwhile, the thickness of the barrier material layer 201 formed on the sidewall of the contact hole 100a is less than that of the barrier material layer 201 formed on the bottom wall of the contact hole 100a. Therefore, after the barrier material layer 201 on the sidewall of the contact hole 100a is etched, a portion of the barrier material layer 201 on the bottom wall of the contact hole 100a is still remained. The remaining portion of the barrier material layer 201 forms the barrier layer 200.

Of course, the barrier material layer 201 arranged on the sidewall of the contact hole 100a may also be removed in other manners. In other methods, the barrier material layer 201 on the bottom wall of the contact hole 100a may not be removed. Alternatively, in other embodiments, the barrier material layer 201 may also be deposited on the inner wall of the contact hole 100a through other methods, which is not limited thereto in the disclosure.

In one embodiment, S400 includes the following operations.

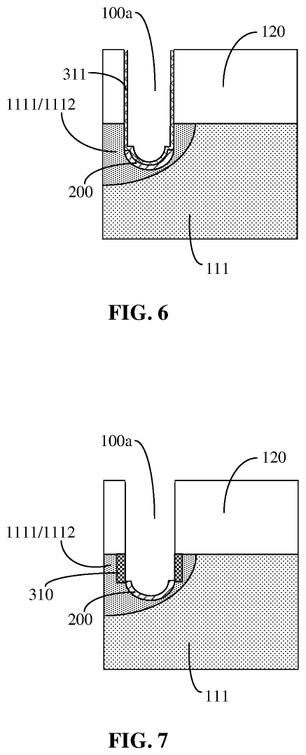

In S410, a contact raw material layer 311 is formed on a sidewall of the contact hole 100a and on the barrier layer 200 on the basis of a second mask, in which the second mask is provided with a second opening, and the second opening exposes the contact hole 100a, with reference to FIG. 6.

In S420, the contact raw material layer 311 is diffused into the at least one of the source area 1111 or the drain area 1112 with a crystallization reaction being occurred between the contact raw material layer 311 and the at least one of the source area 1111 or the drain area 1112, so as to form the contact layer 310, with reference to FIG. 7.

In S410, the second mask and the first mask in S310 may be the same mask. Of course, the first mask and second mask may be different masks.

A material of the contact raw material layer 311 may be a metal material, such as cobalt.

In S420, a heat treatment may be performed on a structure in which the contact raw material layer 311 is formed on the inner wall of the contact hole 100a, so that the contact raw material layer 311 is diffused into at least one of the source area 1111 or the drain area 1112 with a crystallization reaction being occurred between the contact raw material layer 311 and the at least one of the source area 1111 or the drain area 1112, so as to form the contact layer 310.

A material of the contact layer 310 may be a metal silicide, such as cobalt silicide.

Herein, it can be understood that a portion of the contact raw material layer 311 which is not diffused into at least one of the source area 1111 or the drain area 1112 (for example, the contact raw material layer 311 aligned with the dielectric layer 120, and the contact raw material layer 311 on the barrier layer 200) may be remained to serve as a composition of the conductive contact structure 300 (not shown). Of course, the contact raw material layer 311 not forming the contact layer 310 may also be removed, which is not limited thereto in the disclosure.

The contact layer 310 formed in this embodiment is arranged between the contact hole 100a and at least one of the source area 1111 or the drain area 1112, that is, the contact layer 310 is formed outside the contact hole 100a. Of course, in other embodiments, in an implementable case, the contact layer 310 may also be formed on the inner wall of the contact hole 100a, which is not limited thereto in the disclosure.

In one embodiment, the conductive contact structure 300 further includes a conductive metal structure 320. After S420, S400 further includes the following operations.

In S430, the contact hole 100a is filled with the conductive metal structure 320, with reference to FIG. 8.

As an example, a material of the conductive metal structure 320 may be at least one of tungsten, molybdenum, or aluminum. The conductive metal structure can connect the current of at least one of the source area 1111 or the drain area 1112 to the outside.

In this case, the contact layer 310 is arranged between the conductive metal structure 320 and at least one of the source area 1111 or the drain area 1112. The barrier layer 200 is arranged between the conductive metal structure 320 and the active area 111 arranged below the contact hole 100a.

In one embodiment, with reference to FIG. 8 or FIG. 9, a semiconductor structure is further provided, which includes a base 100, a contact hole 100a, a barrier layer 200, and a conductive contact structure 300.

The base 100 includes an active area 111. A drain area 1112 and a source area 1111 are formed in the active area 111. The contact hole 100a extends from a surface of the base 100 to at least one of the source area 1111 or the drain area 1112. The barrier layer 200 is arranged on a bottom surface of the conductive contact structure 300. The contact hole 100a is filled with the conductive contact structure 300, and the conductive contact structure 300 includes a contact layer 310. The contact layer 310 is in contact with the at least one of the source area 1111 or the drain area 1112.

In this embodiment, the barrier layer 200 is arranged on the bottom surface of the conductive contact structure 300, so as to effectively prevent the contact layer 310 from concentrating below the conductive contact structure 300. In this case, the contact layer 310 can provide a good current transmission by forming a good ohmic contact between the side surface of the contact layer and at least one of the source area 1111 or the drain area 1112, so as to effectively reduce the transverse resistance, thereby effectively increasing the current of the source and the drain.

In one embodiment, the base 100 includes a substrate 110 and a dielectric layer 120. The substrate 110 includes the active area 111. The dielectric layer 120 is arranged on the substrate 110. The contact hole 100a extends from a surface of the dielectric layer 120 to the at least one of the source area 1111 or the drain area 1112.

In one embodiment, the barrier layer 200 is arranged inside the contact hole 100a.

In one embodiment, the contact hole 100a extends from the surface of the base 100 to the active area 111 arranged below the at least one of the source area 1111 or the drain area 1112. The thickness of the barrier layer 200 is greater than the depth of the contact hole 100a extending into the active area 111 arranged below the at least one of the source area 1111 or the drain area 1112 (with reference to FIG. 9).

In one embodiment, the contact layer 310 is arranged between the contact hole 100a and the at least one of the source area 1111 or the drain area 1112.

In one embodiment, the conductive contact structure 300 further includes a conductive metal structure 320. The contact hole 100a is filled with the conductive metal structure 320, and the contact layer 310 is arranged between the conductive metal structure 320 and the at least one of the source area 1111 or the drain area 1112. The barrier layer 200 is arranged between the conductive metal structure 320 and the active area 111 arranged below the contact hole 100a.

In one embodiment, a material of the conductive metal structure 320 is at least one of tungsten, molybdenum, or aluminum.

Specific definition of the semiconductor structure may refer to the definition of the method for manufacturing the semiconductor structure described above, which will not be repeated herein.

It should be understood that, although the steps in the flowchart of FIG. 1 are shown in order as indicated by the arrows, these steps are not necessarily executed in order indicated by the arrows. Unless otherwise indicated herein, the steps are not executed in the exact order shown and may be executed in other orders. In addition, at least a portion of the steps in FIG. 1 may include a plurality steps or a plurality of stages, which are not necessarily executed at the same time, but may be executed at different times, and the order of execution is not necessarily sequential, but may be executed in turns or alternately with other steps or at least a portion of the steps or stages of other steps.

In the description of this specification, the description with reference to the terms “some embodiments”, “other embodiments”, “ideal embodiments” and the like means that the specific features, structures, materials or features described in combination with these embodiments or examples are included in at least one embodiment or example of the disclosure. In the specification, the schematic descriptions of the abovementioned terms do not necessarily mean the same embodiment or example.

The technical features of the embodiments described above may be arbitrarily combined. In order to make the description simple, not all the possible combinations of the technical features in the above embodiments are completely described. However, as long as there is no contradiction in the combinations of these technical features, all of the combinations of these technical features should be considered as within the scope described in this specification.

The above embodiments merely illustrate several implementations of the disclosure, and the description thereof is specific and detailed, and they are not constructed as limiting the patent scope of the disclosure. It should be noted that a number of variations and improvements made by those of ordinary skill in the art without departing from the conception of the disclosure are within the protection scope of the disclosure. Therefore, the patent protection scope of the disclosure should be subjected to the appended claims.

1. A semiconductor structure, comprising a base, a contact hole, a barrier layer, and a conductive contact structure,
wherein the base comprises an active area, and a drain area and a source area are formed in the active area;
wherein the contact hole extends from a surface of the base to at least one of the source area or the drain area;
wherein the barrier layer is arranged on a bottom surface of the conductive contact structure; and
wherein the contact hole is filled with the conductive contact structure, and the conductive contact structure comprises a contact layer, wherein the contact layer is in contact with the at least one of the source area or the drain area.

2. The semiconductor structure according to claim 1, wherein the base comprises a substrate and a dielectric layer, wherein the substrate comprises the active area, the dielectric layer is arranged on the substrate, and the contact hole extends from a surface of the dielectric layer to the at least one of the source area or the drain area.

3. The semiconductor structure according to claim 1, wherein the barrier layer is arranged inside the contact hole.

4. The semiconductor structure according to claim 3, wherein the contact hole extends from the surface of the base to the active area arranged below the at least one of the source area or the drain area, and the barrier layer covers a portion, which extends beyond the at least one of the source area or the drain area and into the active area, of the contact hole.

5. The semiconductor structure according to claim 1, wherein the contact layer is arranged between the contact hole and the at least one of the source area or the drain area.

6. The semiconductor structure according to claim 5, wherein the conductive contact structure further comprises a conductive metal structure, wherein the contact hole is filled with the conductive metal structure, the contact layer is arranged between the conductive metal structure and the at least one of the source area or the drain area, and the barrier layer is arranged between the conductive metal structure and the active area arranged below the contact hole.

7. The semiconductor structure according to claim 6, wherein a material of the conductive metal structure is at least one of tungsten, molybdenum, or aluminum.

8. The semiconductor structure according to claim 1, wherein a material of the contact layer is a metal silicide.

9. A method for manufacturing a semiconductor structure, comprising:
providing a base, wherein the base comprises an active area, and a drain area and a source area are formed in the active area;
forming a contact hole in the base, wherein the contact hole extends from a surface of the base to at least one of the source area or the drain area;
forming a barrier layer; and
forming a conductive contact structure,
wherein the barrier layer is arranged on a bottom surface of the conductive contact structure, the contact hole is filled with the conductive contact structure, and the conductive contact structure comprises a contact layer, wherein the contact layer is in contact with the at least one of the source area or the drain area.

10. The method for manufacturing the semiconductor structure according to claim 9, wherein the base comprises a substrate and a dielectric layer, wherein the substrate comprises the active area, the dielectric layer is arranged on the substrate, and the contact hole extends from a surface of the dielectric layer to the at least one of the source area or the drain area.

11. The method for manufacturing the semiconductor structure according to claim 9, wherein the barrier layer is arranged inside the contact hole.

12. The method for manufacturing the semiconductor structure according to claim 11, wherein forming the barrier layer comprises:
forming a barrier material layer on an inner wall of the contact hole on the basis of a first mask, wherein the first mask is provided with a first opening, and the first opening exposes the contact hole; and
removing at least a portion, which is arranged on a sidewall of the contact hole, of the barrier material layer, wherein a remaining portion of the barrier material layer forms the barrier layer.

13. The method for manufacturing the semiconductor structure according to claim 12, wherein forming the barrier material layer on the inner wall of the contact hole on the basis of the first mask comprises:
depositing the barrier material layer on the inner wall of the contact hole on the basis of the first mask through an atomic layer deposition process.

14. The method for manufacturing the semiconductor structure according to claim 13, wherein removing at least the portion, which is arranged on the sidewall of the contact hole, of the barrier material layer comprises:
etching the barrier material layer through an isotropic etching process.

15. The method for manufacturing the semiconductor structure according to claim 9, wherein forming the conductive contact structure comprises:
forming a contact raw material layer on a sidewall of the contact hole and on the barrier layer on the basis of a second mask, wherein the second mask is provided with a second opening, and the second opening exposes the contact hole; and
diffusing the contact raw material layer into the at least one of the source area or the drain area with a crystallization reaction being occurred between the contact raw material layer and the at least one of the source area or the drain area, to form the contact layer.

16. The method for manufacturing the semiconductor structure according to claim 15, wherein a material of the contact layer is a metal silicide.

17. The method for manufacturing the semiconductor structure according to claim 15, wherein the conductive contact structure further comprises a conductive metal structure, and wherein after diffusing the contact raw material layer into the at least one of the source area or the drain area with a crystallization reaction being occurred between the contact raw material layer and the at least one of the source area or the drain area, to form the contact layer, forming the conductive contact structure further comprises:
filling the contact hole with the conductive metal structure.

18. The method for manufacturing the semiconductor structure according to claim 17, wherein a material of the conductive metal structure is at least one of tungsten, molybdenum, or aluminum.
